(19) United States
(12) Patent Application Publication
(10) Pub. No.: US 2026/0153564 A1
(43) Pub. Date: Jun. 4, 2026

(54) BATTERY DETERIORATION PREDICTION SYSTEM, BATTERY DETERIORATION PREDICTION METHOD, AND STORAGE MEDIUM

(71) Applicant: TOYOTA JIDOSHA KABUSHIKI KAISHA, Toyota-shi (JP)

(72) Inventors: Masaaki Inoue, Tokyo (JP); Hideaki Bunazawa, Tokyo (JP); Shintaro Fukushima, Tokyo (JP); Masanori Okamoto, Tokyo (JP)

(73) Assignee: TOYOTA JIDOSHA KABUSHIKI KAISHA, Toyota-shi (JP)

(21) Appl. No.: 19/310,002

(22) Filed: Aug. 26, 2025

(30) Foreign Application Priority Data
Dec. 2, 2024 (JP) 2024-209234

(51) Int. Cl. G01R 31/367; G01R 31/392

(52) U.S. Cl. CPC G01R 31/367; G01R 31/392

(57) ABSTRACT

A battery deterioration prediction system using a prediction model includes a reliability calculation unit configured to calculate a prediction reliability using a difference between a predicted SOH value of a target battery calculated using the prediction model and an actually measured SOH value, and a model adjustment unit configured to adjust the prediction model when the prediction reliability exceeds a predetermined threshold value. Thus, the model to be used is adjusted by providing a quantitative prediction reliability to the output.

### CROSS-REFERENCE TO RELATED APPLICATION

This application claims priority to Japanese Patent Application No. 2024-209234 filed on Dec. 2, 2024. The disclosure of the above-identified application, including the specification, drawings, and claims, is incorporated by reference herein in its entirety.

### BACKGROUND

### 1. Technical Field

The present disclosure relates to a battery deterioration prediction system, a battery deterioration prediction method, and a storage medium.

### 2. Description of Related Art

In recent years, there have been used technologies of diagnosing and predicting battery deterioration using, as inputs, physical or chemical deterioration characteristics of the battery and usage history such as elapsed period, energization amount, state of charge (SOC), and temperature.

Japanese Unexamined Patent Application Publication No. 2013-089424 (JP 2013-089424 A) discloses that an objective function is constructed by combining a model in which an aging part and a current-carrying part of a battery are separated and a calculation model such as a root law, a table of a discharge coefficient ha(T, S) and a current-carrying coefficient ac(T, S) is created using a solver etc., where T is a temperature and S is an SOC, and battery deterioration is predicted based on the table.

### SUMMARY

In the related existing technologies, the adaptability and robustness of the predicted output based on the physical and chemical deterioration characteristics of the battery cannot be adjusted. Therefore, there is a risk that the model may have good robustness but poor adaptability to individuals, or that the model may have good adaptability to specific individuals but poor robustness and poor generalization performance.

There is also known a technology of converting time-series data of battery voltage or SOC, temperature, current, etc. into intermediate data, thereby inputting the data as latent features without explicitly indicating the physical and chemical deterioration characteristics of the data. In this method, however, the physical and chemical deterioration characteristics cannot be guaranteed. Therefore, a reasonable prediction reliability cannot be calculated and feedback cannot even be provided. Thus, it is not possible to eliminate the risk that the model may have poor adaptability to individuals or poor generalization performance.

Further, there is known a technology of, when additional measured data is input, correcting a prediction formula by evaluating a deviation from a predicted value. In this correction method, however, the adjustment of the contribution of the physical and chemical deterioration characteristics cannot be reflected in the intensity of the correction. Thus, it is not possible to eliminate the risk that the model may have poor adaptability to individuals or poor generalization performance.

The present disclosure provides a battery deterioration prediction system, a battery deterioration prediction method, and a storage medium in which adaptability and robustness can be adjusted.

A battery deterioration prediction system according to the present disclosure is a battery deterioration prediction system using a prediction model. The battery deterioration prediction system includes: a reliability calculation unit configured to calculate a prediction reliability using a difference between a predicted state-of-health value of a target battery calculated using the prediction model and an actually measured state-of-health value; and a model adjustment unit configured to adjust the prediction model when the prediction reliability exceeds a predetermined threshold value.

Thus, the model to be used can be adjusted by providing a quantitative prediction reliability to the output.

A battery deterioration prediction method according to the present disclosure is a battery deterioration prediction method using a prediction model. The battery deterioration prediction method includes: calculating a prediction reliability using a difference between a predicted state-of-health value of a target battery calculated using the prediction model and an actually measured state-of-health value; and adjusting the prediction model when the prediction reliability exceeds a predetermined threshold value.

Thus, the model to be used can be adjusted by providing a quantitative prediction reliability to the output.

A storage medium according to the present disclosure is a storage medium storing a battery deterioration prediction program using a prediction model. The battery deterioration prediction program causes a computer to: calculate a prediction reliability using a difference between a predicted state-of-health value of a target battery calculated using the prediction model and an actually measured state-of-health value; and adjust the prediction model when the prediction reliability exceeds a predetermined threshold value.

Thus, the model to be used can be adjusted by providing a quantitative prediction reliability to the output.

According to the present disclosure, it is possible to provide the battery deterioration prediction system, the battery deterioration prediction method, and the storage medium in which adaptability and robustness can be adjusted.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram showing the configuration of a deterioration prediction system according to a first embodiment;

FIG. 2 is a flowchart of the operation of the deterioration prediction system according to the first embodiment;

FIG. 3 is a diagram showing an example of a prediction model f of an SOH at future time t according to the first embodiment;

FIG. 4 is a diagram showing an overall calculation flow of prediction reliability according to the first embodiment;

FIG. 5 is a diagram showing an example of a prediction reliability system according to the first embodiment; and

FIG. 6 is a diagram showing another example of the prediction reliability system according to the first embodiment.

### DETAILED DESCRIPTION OF EMBODIMENTS

### First Embodiment

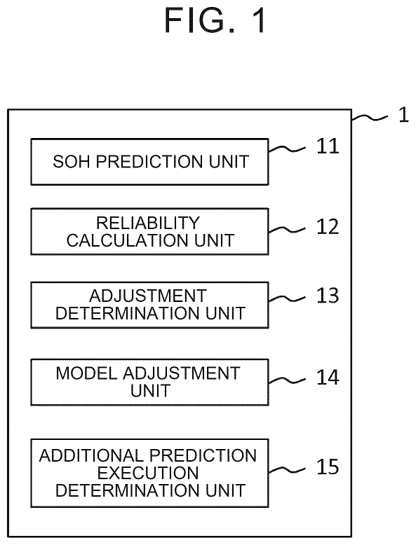

Hereinafter, a battery deterioration prediction system according to an embodiment will be described with reference to the drawings. FIG. 1 is a block diagram showing an example of the configuration of a deterioration prediction system 1. The deterioration prediction system 1 includes a state-of-health (SOH) prediction unit 11, a reliability calculation unit 12, an adjustment determination unit 13, a model adjustment unit 14, and an additional prediction execution determination unit 15. The battery is a secondary battery mounted on a vehicle, and the description will be given under the assumption that a plurality of batteries is typically provided on the vehicle.

The SOH prediction unit 11 predicts a value by evaluating the state of the battery in comparison with an ideal state. In other words, the SOH prediction unit 11 can predict the state of health and deterioration of the battery.

More specifically, the SOH prediction unit 11 receives, as input, an SOH history x=[x(0), . . . , x(t′)] of a target battery that satisfies t′<t for any future time t. Then, the SOH prediction unit 11 predicts a future SOH y(t) at time t as y(t)=f(x|θ) using a future SOH prediction model f. In the equation, θ is a parameter of the model f.

The reliability calculation unit 12 calculates a prediction reliability C(t) of the output y(t) of the SOH prediction model that is output by the SOH prediction unit 11 by calculation g(x, f) of a reliability calculation model g.

The adjustment determination unit 13 determines whether to execute model adjustment of the SOH prediction model f used in the SOH prediction unit 11 based on the result of the prediction reliability C(t) calculated by the reliability calculation unit 12.

The model adjustment unit 14 adjusts the balance between the adaptability and robustness of the SOH model f by changing the parameter θ.

The additional prediction execution determination unit 15 uses a new input x′ to determine whether to execute further prediction.

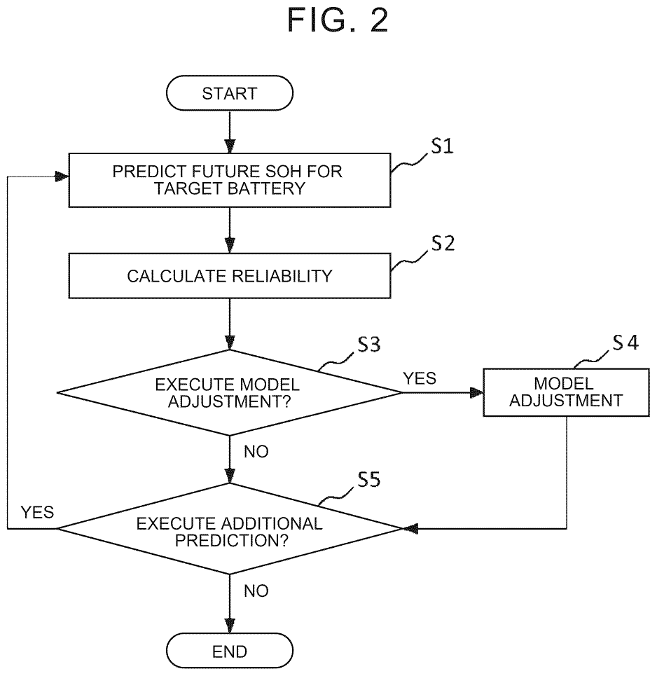

Next, the operation flow of the deterioration prediction system 1 will be described with reference to FIG. 2.

The SOH prediction unit 11 predicts a value by evaluating the state of the battery in comparison with an ideal state (step S1).

The reliability calculation unit 12 calculates a prediction reliability C(t) of the output y(t) of the SOH prediction model by calculation g(x, f) of the reliability calculation model g (step S2).

The adjustment determination unit 13 determines whether to execute model adjustment of the SOH prediction model f based on the result of the prediction reliability C(t) calculated by the reliability calculation unit 12 (step S3). When the adjustment determination unit 13 determines to execute the adjustment (Yes in step S3), the process proceeds to step S4. When the adjustment determination unit 13 determines not to execute the adjustment (No in step S3), the process proceeds to step S5.

The model adjustment unit 14 adjusts the SOH model f (step S4). Then, the process proceeds to step S5.

The additional prediction execution determination unit 15 uses a new input x′ to determine whether to execute additional prediction (step S5). When determination is made to execute the additional prediction (Yes in step S5), the process returns to step S1. When determination is made not to execute the additional prediction (No in step S5), the process ends.

Next, a detailed operation example in each step shown in FIG. 2 will be described. First, the calculation of the future SOH y(t) at time t by the SOH prediction unit 11 in step S1 will be described.

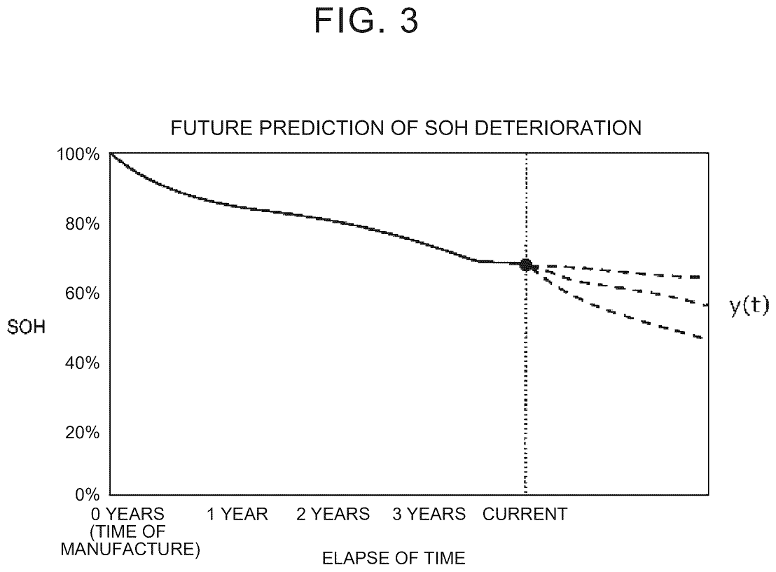

The SOH prediction unit 11 predicts the future SOH of the target battery using a secondary battery SOH prediction model based on the physical and chemical characteristics of battery deterioration. FIG. 3 is a diagram showing an example of the prediction model f of the SOH at future time t.

As described above, the SOH prediction unit 11 receives, as input, the SOH history x=[x(0), . . . , x(t′)] of the target battery that satisfies t′<t for any future time t. Then, the SOH prediction unit 11 calculates the future SOH y(t) at time t by y(t)=f(x|θ) using the prediction model f. In the equation, θ is a parameter of the model f. At this time, the SOH prediction unit 11 can include, in the SOH history x, battery-related information that is information on conditions related to the battery that affect SOH deterioration as information other than the time-series information of actual values of the SOH itself.

The battery-related information includes, but is not limited to, the characteristics of the battery, the characteristics of the vehicle including the battery, a travel environment and vehicle condition history of the vehicle including the battery, and a driving and charging operation history of the vehicle including the battery.

Examples of the characteristics of the battery include a full charge capacity of the battery, materials of a cathode, an anode, and an electrolyte, and a manufacturer. Examples of the characteristics of the vehicle including the battery include a vehicle model, performance such as average fuel efficiency, and a vehicle weight. Examples of the travel environment and vehicle condition history of the vehicle including the battery include frequency distributions of a travel area, an SOC during travel, and battery temperature. Examples of the driving and charging operation history of the vehicle including the battery include the number of sudden accelerations and decelerations, and the ratio of quick charging to normal charging.

The SOH prediction model f may be an SOH prediction model such as electrode deterioration behavior according to the Arrhenius equation or a root law of deterioration over time. This is a known technology that can predict the SOH based on the physical and chemical characteristics of battery deterioration.

The parameter θ used in the model f may be calculated in advance, or may newly be calculated using the SOH history x.

Next, an example of the calculation of the prediction reliability by the reliability calculation unit 12 in step S2 will be described. Description will be given of both cases where the deterioration prediction system 1 can acquire the SOH history x=[x(0), . . . , x(t′)] for a plurality of batteries and where the deterioration prediction system 1 cannot acquire the SOH history x=[x(0), . . . , x(t′)] for a plurality of batteries.

First, description will be given of the case where the deterioration prediction system 1 cannot acquire the SOH history for a plurality of batteries, that is, can acquire the SOH history only for a single battery.

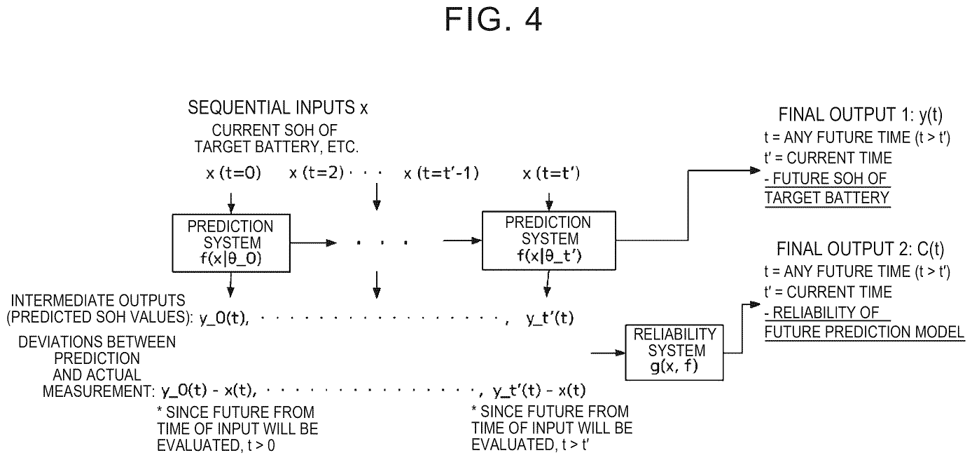

First, the reliability calculation unit 12 executes calculation on the input of the reliability system. FIG. 4 is a diagram showing an example of the overall calculation flow of the prediction reliability. As shown in FIG. 4, the reliability calculation unit 12 regards the past SOH history x=[x(0), . . . , x(t′)] as sequential inputs in order from the oldest time, and calculates predicted outputs y_0(t), . . . , y_t′(t) of the prediction system at individual times using x up to a certain time, such as [x(0)], [x(0,x(1)], [x(0), x(1), x(2)], . . . , [x(0), . . . , x(t′)], and deviations y_0(t)−x(t), . . . , y_t′(t)−x(t) of the predicted outputs of the model at individual times.

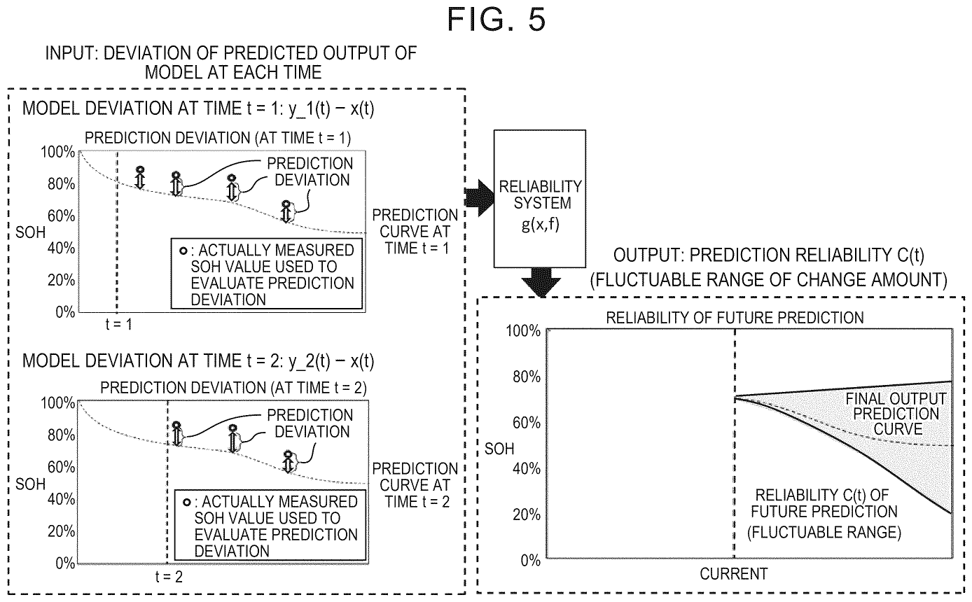

Next, the reliability calculation unit 12 calculates the prediction reliability by the reliability system. FIG. 5 is a diagram showing an example of the prediction reliability system. As shown in FIG. 5, the reliability calculation unit 12 uses the deviations y_0(t)−x(t), . . . , y_t′(t)−x(t) of the predicted outputs of the model at individual times to calculate, by a method such as regression, an expected degree of prediction deviation between the model creation time and future time for prediction, and provides it as a prediction reliability C(t) for the final output y(t) of future SOH prediction.

Next, description will be given of the case where the deterioration prediction system 1 can acquire the SOH history x=[x(0), . . . , x(t′)] for a plurality of batteries.

First, the reliability calculation unit 12 executes calculation on the input of the reliability system. Specifically, the reliability calculation unit 12 executes, for each of the batteries, the above calculation of the deviations of the predicted outputs of the model at individual times as the reliability for a single battery.

That is, the reliability calculation unit 12 calculates, for the plurality of batteries, predicted outputs y_i=[y_0(t), . . . , y_t′(t)] of the prediction system for a battery i and deviations e_i=[y_0(t)−x(t), . . . , y_t′(t) −x(t)] of the predicted outputs of the model at individual times. When there is SOH history data for n batteries, i=0, . . . , n−1.

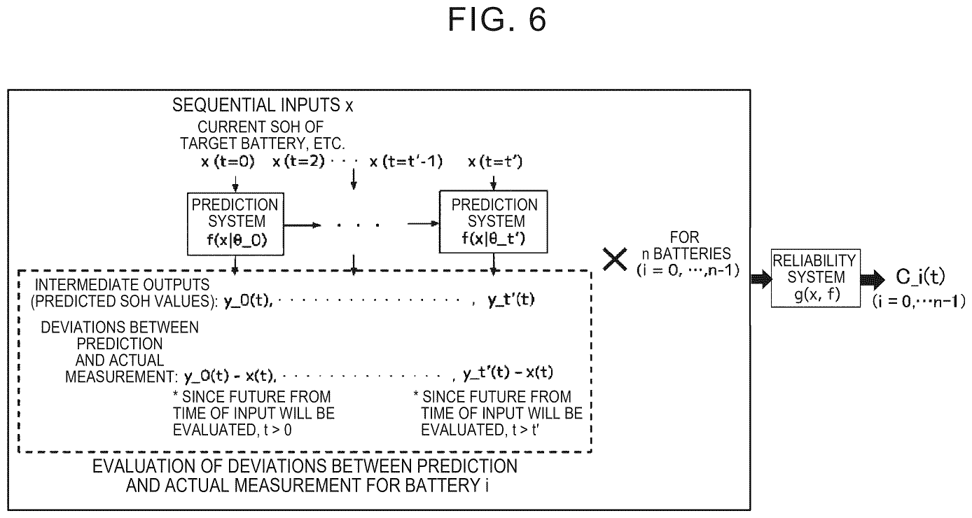

Next, the reliability calculation unit 12 uses the calculated predicted outputs y_i=[y_0(t), . . . , y_t′(t)] of the prediction system and the calculated deviations e_i=[y_0(t)−x(t), . . . , y_t′(t)−x(t)] of the predicted outputs of the model at individual times for the n batteries to calculate the prediction reliability. FIG. 6 is a diagram showing another example of the prediction reliability system. As shown in FIGS. 4 and 6, the reliability calculation unit 12 receives n pairs of (y_i, e_i) as input and calculates, by a method such as regression, an expected degree of prediction deviation between the model creation time and future time for prediction. Then, the reliability calculation unit 12 provides it as a prediction reliability C_i(t) for the final output y_i(t) of future SOH prediction.

Thus, the reliability calculation unit 12 can calculate the prediction reliability using the difference between the predicted SOH value of the target battery calculated using the prediction model and the actually measured SOH value.

Next, an example of the determination as to whether to execute model adjustment by the adjustment determination unit 13 in step S3 will be described.

The adjustment determination unit 13 determines whether to execute model adjustment based on the prediction reliability C(t) output by the reliability calculation unit 12.

For example, the adjustment determination unit 13 determines to execute adjustment on the prediction model when C_i(t) exceeds a preset threshold value, i.e., is poor, with respect to y(t), regardless of whether the SOH history is acquired for a single battery or a plurality of batteries in the process of step S2.

For example, in the case where the SOH history can be acquired for a plurality of batteries in the process of step S2, the adjustment determination unit 13 can determine to execute adjustment on the battery prediction model when C_i(t) is relatively large, i.e., relatively poor, in comparison with the other batteries. That is, the adjustment determination unit 13 can use the values of C_i(t) of the other batteries as threshold values for the target battery, and make the determination based on whether the threshold values are exceeded.

From the above, in the adjustment determination unit 13, the calculation as to whether the prediction reliability exceeds the predetermined threshold value can be changed depending on whether the actually measured SOH value of the battery has been acquired from a plurality of batteries.

Next, the model adjustment by the model adjustment unit 14 in step S4 will be described.

The model adjustment unit 14 adjusts the balance between the adaptability and robustness of the model f by changing the parameter θ. The model adjustment unit 14 adjusts the trade-off between the adaptability and robustness of the prediction model using physical domain knowledge of battery deterioration, such as a deterioration mode or a root law. The current time is represented by t_{now} and the future time for SOH prediction is represented by t_{future}. Then, the following feedback of the prediction reliability C(t) is given as an example.

During parameter learning, the model adjustment unit 14 changes the weight of learning data according to a battery deterioration mode (early deterioration, intermediate deterioration, or late deterioration) determined by t_{now} for each battery. To improve, for example, the adaptability, the model adjustment unit 14 increases the weight of battery data in a deterioration mode close to the prediction target (close to t_{now}) during the parameter learning. To improve the robustness, the model adjustment unit 14 reduces the weight of battery data in the deterioration mode close to the prediction target (close to t_{now}).

During the parameter learning, for the range of t_{future} in which the prediction reliability C(t) is large, the model adjustment unit 14 can improve the robustness by fitting the prediction model to a general deterioration curve that is not dependent on individual batteries, such as a root law.

Thus, the model adjustment unit 14 can adjust the prediction model when the prediction reliability exceeds the predetermined threshold value in the determination made by the adjustment determination unit 13.

Next, an example of the determination as to whether to execute additional prediction by the additional prediction execution determination unit 15 in step S5 will be described.

The additional prediction execution determination unit 15 determines to execute additional prediction when there is a new input x′, for example, as shown below.

The additional prediction execution determination unit 15 determines to execute additional prediction when the latest data is added to the original input x=[x(0), . . . , x(t′)], resulting in x′=[x(0), . . . , x(t′), x(t′+1)]. This is the assumption of a situation where data accumulates over time.

The additional prediction execution determination unit 15 determines to execute additional prediction when a new feature z is added to the original input x =[x(0), . . . , x(t′)], resulting in x′=[x(0), z(0), . . . , x(t′), z(t′)]. This is the assumption of a case where information from another database is added.

The additional prediction execution determination unit 15 determines to execute additional prediction when a new battery SOH history is added to the original input x=[x(0), . . . , x(t′)], resulting in x′=[x, x_add]. This is the assumption of, for example, a case where later battery data is added.

The additional prediction execution determination unit 15 may determine to execute additional prediction even if the original input x=[x(0), . . . , x(t′)] is directly used as x′=x. This means that the input remains as it is and the adjusted output can be acquired using the adjusted model.

In this way, the additional prediction execution determination unit 15 can determine whether to execute additional prediction when the prediction reliability does not exceed the predetermined threshold value in the determination made by the adjustment determination unit 13, or when the prediction reliability exceeds the predetermined threshold value in the determination made by the adjustment determination unit 13 and the model adjustment unit 14 has adjusted the prediction model.

From the above, the deterioration prediction system 1 can calculate the prediction reliability based on the SOH history and execute model adjustment according to the prediction reliability. The deterioration prediction system 1 can adjust the balance between the adaptability and robustness of the model by changing the parameter used in the model.

The present disclosure is not limited to the above embodiment, and can be modified as appropriate without departing from the spirit and scope of the present disclosure. That is, the above description has been omitted or simplified as appropriate for the purpose of clarity, and a person skilled in the art can easily modify, add, or convert each element of the embodiment within the scope of the present disclosure.

The embodiment of the present disclosure may be implemented by hardware or special-purpose circuitry, software, logic, or any combination thereof. Some aspects may be implemented by hardware, while other aspects may be implemented by firmware or software that may be executed by a controller, a microprocessor or any other computing device.

The present disclosure also provides at least one computer program product tangibly stored in a non-transitory computer-readable storage medium. The computer program product contains computer-executable instructions such as instructions contained in program modules that are executed on a target real or virtual processor device to perform the process or method of the present disclosure. The program modules include routines, programs, libraries, objects, classes, components, data structures, etc. that perform specific tasks or implement specific abstract data types. The functions of the program modules may be combined or split between program modules as desired in various embodiments. The machine-executable instructions in the program modules can be executed in local or distributed devices. In the distributed devices, the program modules can be located in both local and remote storage media.

Program codes for performing the method of the present disclosure may be written in any combination of one or more programming languages. These program codes are provided to a processor or controller of a general-purpose computer, a special-purpose computer, or any other programmable data processing device. When the program codes are executed by the processor or controller, the functions and operations in the flowchart and/or the implementation block diagram are performed. The program codes may be executed entirely on a machine, partly on a machine, as a stand-alone software package, partly on a machine and partly on a remote machine, or entirely on a remote machine or server.

The program may be stored and provided to a computer using various types of non-transitory computer-readable media (storage media). The non-transitory computer-readable media include various types of tangible recording media. Examples of the non-transitory computer-readable media include magnetic recording media, magneto-optical recording media, optical disc media, and semiconductor memories. Examples of the magnetic recording media include flexible disks, magnetic tapes, and hard disk drives. Examples of the magneto-optical recording media include magneto-optical disks. Examples of the optical disc media include Blu-ray discs, compact disc (CD)-read only memories (ROMs), CD-R (recordable), and CD-RW (rewritable). Examples of the semiconductor memories include solid state drives, mask ROMs, programmable ROMs (PROMs), erasable PROMs (EPROMs), flash ROMs, and random access memories (RAMs). The program may also be provided to the computer by various types of transitory computer-readable media. Examples of the transitory computer-readable media include electrical signals, optical signals, and electromagnetic waves. The transitory computer-readable medium can provide the program to the computer via a wired communication path such as an electric wire or an optical fiber, or via a wireless communication path.

What is claimed is:

1. A battery deterioration prediction system using a prediction model, the battery deterioration prediction system comprising:
a reliability calculation unit configured to calculate a prediction reliability using a difference between a predicted state-of-health value of a target battery calculated using the prediction model and an actually measured state-of-health value; and
a model adjustment unit configured to adjust the prediction model when the prediction reliability exceeds a predetermined threshold value.

2. The battery deterioration prediction system according to claim 1, further comprising an additional prediction execution determination unit configured to determine whether to execute additional prediction when the prediction reliability does not exceed the predetermined threshold value, or when the prediction reliability exceeds the predetermined threshold value and the prediction model has been adjusted.

3. The battery deterioration prediction system according to claim 1, further comprising an adjustment determination unit configured to execute calculation as to whether the prediction reliability exceeds the predetermined threshold value, wherein
the adjustment determination unit is configured to change the calculation as to whether the prediction reliability exceeds the predetermined threshold value depending on whether the actually measured state-of-health value of the battery has been acquired from a plurality of batteries.

4. A battery deterioration prediction method using a prediction model, the battery deterioration prediction method comprising:
calculating a prediction reliability using a difference between a predicted state-of-health value of a target battery calculated using the prediction model and an actually measured state-of-health value; and
adjusting the prediction model when the prediction reliability exceeds a predetermined threshold value.

5. A non-transitory storage medium storing a battery deterioration prediction program using a prediction model, the battery deterioration prediction program causing a computer to:
calculate a prediction reliability using a difference between a predicted state-of-health value of a target battery calculated using the prediction model and an actually measured state-of-health value; and
adjust the prediction model when the prediction reliability exceeds a predetermined threshold value.
